(19) United States
(12) Patent Application Publication
(10) Pub. No.: US 2012/0132254 A1
(43) Pub. Date: May 31, 2012

(54) SOLAR TRACKER DEVICE

(76) Inventor: Oren Aharon, Haifa (IL)

(21) Appl. No.: 13/304,339

(22) Filed: Nov. 24, 2011

Related U.S. Application Data
(60) Provisional application No. 61/417,238, filed on Nov. 25, 2010.

(51) Int. Cl. H01L 31/052; F24J 2/52

(52) U.S. Cl. 136/246; 126/605

(57) ABSTRACT

A solar tracker device based on a mechanical technique adapted to synchronously rotate mounted solar panels or mirrors along their approximate main axis, in one or two directions. The device enables building large solar fields with multiple panels or mirrors each rotated along its approximate location of its own main axis by single motor per axis.

### CROSS-REFERENCE TO RELATED PATENT APPLICATIONS

This application claims priority from U.S. Provisional Patent Application No. 61/417,238, titled “Apparatus for a solar tracker device”, filed on Nov. 25, 2010, the entire contents of which are incorporated herein by reference.

### FIELD OF THE INVENTION

The present invention relates to solar energy apparatus, in particular a tracker device therefor.

### BACKGROUND OF THE INVENTION

A solar tracker is a device for orienting one or more solar panels or mirrors toward the sun, for example, photovoltaic panels. Tracking can substantially improve the amount of power produced by a solar energy system. Compared to the photovoltaic solar panels, trackers can be relatively inexpensive. This makes trackers particularly advantageous for photovoltaic systems using high-efficiency panels. The required accuracy of the solar tracker depends on the application.

Photovoltaic devices are a leading technology to convert solar energy into electricity. Technologically, photovoltaic power systems are capable of providing energy for any purpose, their main drawback being cost and efficiency. The sun's position in the sky varies both with the seasons (elevation) and time of day as the sun moves across the sky. Solar powered equipment works best when pointed directly or nearly directly toward the sun. Thus, a solar tracker can increase the effectiveness of such equipment over a fixed position panel, and at a relatively low cost.

Current tracker devices are usually built as a sail with multiple solar panels mounted on its surface. Tracking is performed in one or two axes by complicated mechanical systems activated by electrical motor actuators. For economical reasons these tracking devices are large in order to allow mounting of many panels on one surface. This tends to create various problems like wind effect, adverse landscape impact and mechanical and installation problems.

Large tracker systems typically are installed using cranes and require a massive foundation. The foundation and motorized gimbals used have to withstand considerable force even at low wind velocities due to the sail effect created by the large area of mounted panels.

Even mild winds will cause large stability problems and effect total system accuracy. Most trackers have wind sensor and seize normal operation under windy conditions.

Due to the large wind loads and the large mechanical moment of inertia the motors actuating the gimbals system are enormous to provide the necessary moments for system operation. In addition, such large constructions produce an adverse effect on the landscape and are costly to mitigate.

Recently, as the cost of fossil fuel has increased and the adverse effect of fossil energy is clear, the market for solar energy systems has increased dramatically. In addition, other characteristics such as reliability, simplicity, low maintenance and freedom from pollution have increased their popularity even further.

Concentrators equipped with solar cells are still an evolving technology for increasing efficiency of collection but are not yet mature due the high cost involved in building efficient collectors and trackers.

### SUMMARY OF THE INVENTION

The present invention relates to a mechanical approach for tracking the sun where each solar panel or mirror is rotated along its center of gravity and multiple panels are synchronously rotated together by a single motor.

The focus of the invention is to provide a device having cost effective tracking elements to efficiently track the sun and increase the energy that can be converted into electricity. The invention is a simple and reliable system powered by relatively small electric motors for efficient radiation conversion using significantly less electrical power and fewer motors. The present tracker device lowers the overall system cost by reducing the number of motors in the system and optimizing the position of rotating axes.

The present invention addresses the problems of high cost of solar trackers by activating several panels or mirrors with one motor each panel rotating along its approximate center of mass, thus, in its optimal position. The particular mechanical technique enables synchronous movement in two axes for multiple panels arranged in rows and columns, thereby providing an improved tracker relative to the and will substantially free of prior art drawbacks.

It is an object of this invention to provide a solar tracker with improvements in terms of cost, complexity, limited angle, large dimensions, wind sensitivity and so on.

In accordance with embodiments of one aspect of the present invention there is provided a tracker device as defined in for tracking the sun comprising: a plurality of photovoltaic panels or mirrors arranged on rows and columns adapted to synchronously track the sun by two different axes; motor actuators connecting each row and column via a first four bar link mechanism and a second orthogonal four bar link mechanism synchronically moving in parallel each of the photovoltaic panels to track the sun in two different axes; a first motor for rotating all of the rows; a second motor for rotating all of the columns through second four bar link mechanism one for each axis; and a controller for controlling the first and second motors to follow the sun's trajectory.

### BRIEF DESCRIPTION OF THE DRAWINGS

The present invention will be understood and appreciated more fully from the following detailed description taken in conjunction with the appended drawings in which:

FIG. 1 is a schematic layout of an embodiment of the present tracking device; and

FIG. 2 is an example of a prior art multiple panel tracking device.

The following detailed description of embodiments of the invention refers to the accompanying drawings referred to above. Dimensions of components and features shown in the figures are chosen for convenience or clarity of presentation and are not necessarily shown to scale. Wherever possible, the same reference numbers will be used throughout the drawings and the following description to refer to the same and like parts.

### DETAILED DESCRIPTION OF THE INVENTION

Illustrative embodiments of the invention are described below. In the interest of clarity, not all features/components of an actual implementation are necessarily described.

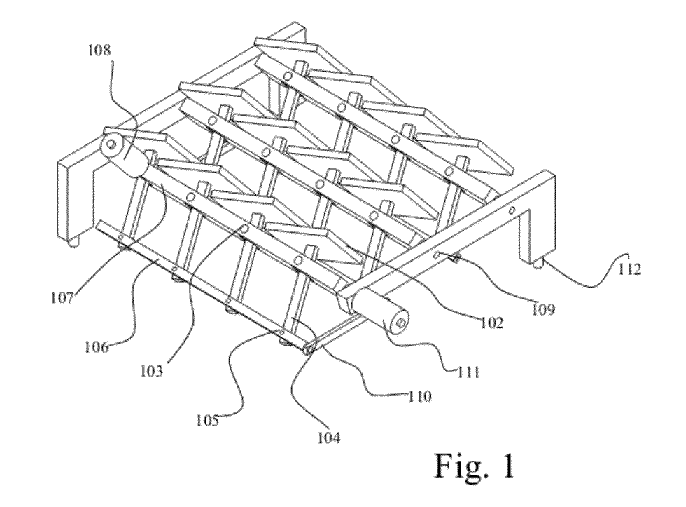

FIG. 1 shows a schematic layout of an embodiment of the present tracking device having multiple mirrors or panels 102 mounted in rows and columns. Each mirror or panel 102 is mounted on a mounting member 104, which is further mounted on a rotating axis 103. Mounting member 104 is further equipped with a parallel second axis of rotation 105. A mechanical link 106 creates a first four bar link by connecting all mounting members 104 in the same row and dictating synchronous parallel rotational movement in that row 107. A first motor actuator 108 allows controlling and aiming of the tracking device in one direction.

Multiple parallel rows are mounted on a frame, each free row free to rotate along its own axis 109. Axis 109 is substantially perpendicular to axis 103. Connecting members 110 connect each row to its neighbor and are allowed to rotate along parallel axis 109 creating a second four bar link perpendicular to the first four bar link. An additional or second motor actuator 111 is capable of rotating the system along axis 109 via the connecting members 110. Activation of both motors actuators 108 and 111 enables parallel solar tracking of all panels 102 in two axes. Motors 108 and 111 are activatable by a controller. The initial position of the tracker is adjustable by a screw (not visible), for example, in legs 112.

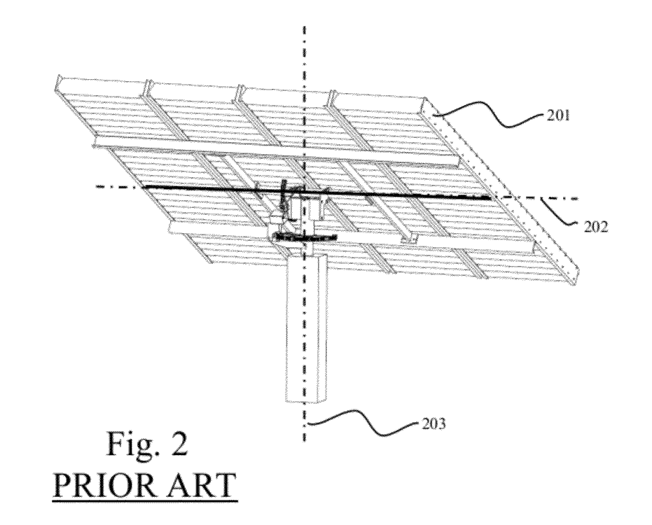

FIG. 2 shows a schematic layout of a prior art tracking device with mounted multiple panels, eight in this case. A panel 201 is mounted on the upper corner and has a large moment of inertia around elevation axis 202 and azimuth axis 203. This large moment of inertia is given by Steiner law as:

I=I∘+Md²

Where I is the moment of inertia; I∘ is the panel's moment of inertia along its principal axis; d is the distance between the panel's principal axis and the current axis of rotation; and M is the panel's mass. This I value is significantly larger than the original I∘ requiring significantly larger motors to move the structure leading to greater costs and complexity. More over the larger structure has also increased sensitivity to winds.

It should be understood that the above description is merely exemplary and that there are various embodiments of the present invention that may be devised, mutatis mutandis, and that the features described in the above-described embodiments, and those not described herein, may be used separately or in any suitable combination; and the invention can be devised in accordance with embodiments not necessarily described above.

What is claimed is:

1. A solar tracker device for tracking the sun comprising:
a plurality of photovoltaic panels or mirrors arranged on rows and columns adapted to synchronously track the sun by two different axes;
motor actuators connecting each row and column via a first four bar link mechanism and a second orthogonal four bar link mechanism synchronically moving in parallel each of the photovoltaic panels to track the sun in two different axes;
a first motor for rotating all of the rows;
a second motor for rotating all of the columns through second four bar link mechanism one for each axis; and
a controller for controlling the first and second motors to follow the sun's trajectory.

2. The device according to claim 1, wherein the center of gravity of the panels is mounted on a member close to the panels' main rotation axis.

3. The device according to claim 1, wherein the two perpendicular four bar link mechanisms include a first four bar link mechanism driven by one electrical device and a second four bar link mechanism manually adjustable according to seasonal change.
